(19) United States
(12) Patent Application Publication
(10) Pub. No.: US 2018/0191336 A1
(43) Pub. Date: Jul. 5, 2018

(54) SYSTEMS AND METHODS FOR POWER MODULES

(71) Applicant: General Electric Company, Schenectady, NY (US)

(72) Inventors: Alvaro Jorge Mari Curbelo, Oberschleissheim (DE); Lucia Fantauzzo, Munich (DE); Fabio Carastro, Munich (DE); Tiziana Bertoncelli, München (DE); Thomas Alois Zoels, Hebertshausen (DE)

(21) Appl. No.: 15/397,485

(22) Filed: Jan. 3, 2017

(51) Int. Cl. H03K 17/041; H05K 1/02

(52) U.S. Cl. CPC H03K 17/041; H05K 1/0254; H05K 2201/10166; H05K 2201/09227; H05K 1/028

(57) ABSTRACT

The systems and methods described herein relate to an adapter driver board for parallel operation of power modules. The systems and methods receive an electrical signal at an input interface of a high voltage adapter board. The systems and methods further deliver the electrical signals to first and second switches along corresponding first and second conductive traces. The first conductive trace extends along the high voltage adapter board and is conductively coupled to the input interface and the first switch. The second conductive trace extending along the high voltage adapter board and is conductively coupled to the input interface and the second switch. The first and second conductive traces are each configured to have an inductance substantially the same. The systems and methods synchronously activate the first and second switches based on the electrical signal.

### FIELD

Embodiments of the subject matter described herein relate to an adapter driver board for parallel operation of power modules.

### BACKGROUND

Some vehicle systems (e.g., locomotives), may employ electric traction motors for driving wheels of the vehicles. In some of these vehicles, the motors are alternating current (AC) motors whose speed and power are controlled by varying the frequency and the voltage of AC electric power supplied to the field windings of the motors. The high electric power may be supplied as DC power that is converted to AC power of controlled frequency and voltage amplitude by a circuit such as an inverter circuit. Conventional inverter circuits include a plurality of semiconductor switches (e.g., insulated gate bipolar transistors, Power MOSFETS, and/or the like) that are switched on and off by driver circuitry in an alternating fashion to produce an output AC waveform.

The high electric power requires high currents provided by the inverter circuits. To achieve this, conventional inverter circuits may need to connect multiple semiconductor switches in parallel by coupling the plurality of semiconductor switches using a plurality of flex cables (e.g., ribbon cables). However, due to differences in impedances between each of the semiconductor switches and driver circuitry the activation/deactivation of each of the semiconductor switches are phase shifted, which in turn crates a current unbalance in the power terminal of the conventional inverter circuit. Additionally, the conventional inverter circuit using flex cabling is fragile and adds expense.

It may be desirable to have an electronic device or circuit, such as an inverter, that differs from those devices or circuits that are currently available.

### BRIEF DESCRIPTION

In an embodiment a system (e.g., a power system) is provided. The system includes a high voltage adapter board coupled to a first module and a second module. The first module is conductively coupled to a first terminal of the high voltage adapter board. A first conductive trace extending along the high voltage adapter board and is conductively coupled to the first terminal. The second module conductively coupled to a second terminal of the high voltage adapter board and a second conductive trace extending along the high voltage adapter board and is conductively coupled to the second terminal. The first conductive trace and the second conductive trace are each conductively coupled to an input interface. The system includes a first switch of the first module and a second switch of the second module. The first switch is conductively coupled to the first terminal and the second switch is conductively coupled to the second terminal. The first and second conductive traces are configured to have an inductance substantially the same such that the first and second conductive traces are configured to synchronously activate the first and second switches.

In an embodiment a method is provided. The method includes receiving an electrical signal at an input interface of a high voltage adapter board. The method includes delivering the electrical signals to first and second switches along corresponding first and second conductive traces. The first conductive trace extends along the high voltage adapter board and is conductively coupled to the input interface and the first switch. The second conductive trace extending along the high voltage adapter board and is conductively coupled to the input interface and the second switch. The first and second conductive traces are each configured to have an inductance substantially the same. The method further includes synchronously activating the first and second switches based on the electrical signal.

In an embodiment a system (e.g., a power system) is provided. The system includes a high voltage adapter board connected to a plurality of modules. Each module includes a first switch conductively coupled to an input interface through conductive traces along the high voltage board. Each of the conductive traces are configured to have an inductance substantially the same such that the conductive traces are configured to synchronously activate the corresponding first switches based on an electrical signal. The system includes a driver circuit positioned remotely with respect to the high voltage adapter board. The driver circuit is conductively coupled to the input interface and communicate the electrical signal to the high voltage adapter board.

### BRIEF DESCRIPTION OF THE DRAWINGS

FIG. 1A illustrates a peripheral view of an embodiment of a power system.

FIG. 1B illustrates an illustration of an embodiment of a module of the power system shown in FIG. 1A.

FIG. 2 illustrates a schematic illustration of an embodiment of a circuit board.

FIG. 3 illustrates a schematic illustration of an embodiment of a circuit board.

FIG. 4A illustrates a peripheral view of an embodiment of a series of conductive traces.

FIG. 4B illustrates a cross-sectional area view of an embodiment of a series of conductive traces.

FIG. 5A illustrates a peripheral view of an embodiment of a series of conductive traces.

FIG. 5B illustrates a cross-sectional area view of an embodiment of a series of conductive traces.

FIG. 6A-B illustrate a cross-sectional area view of embodiments of a series of conductive traces.

FIG. 7 illustrates a peripheral view of an embodiment of first and second conductive traces.

FIG. 8 illustrates a circuit diagram of an embodiment of a portion of the circuit board.

FIG. 9 illustrates a flow chart of a method in accordance with an embodiment.

### DETAILED DESCRIPTION

Various embodiments will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors, controllers or memories) may be implemented in a single piece of hardware (e.g., a general purpose signal processor or random access memory, hard disk, or the like) or multiple pieces of hardware. Similarly, any programs may be stand-alone programs, may be incorporated as subroutines in an operating system, may be functions in an installed software package, and the like. It should be understood that the various embodiments are not limited to the arrangements and instrumentality shown in the drawings.

As used herein, the terms “system,” “unit,” or “module” may include a hardware and/or software system that operates to perform one or more functions. For example, a module, unit, or system may include a computer processor, controller, or other logic-based device that performs operations based on instructions stored on a tangible and non-transitory computer readable storage medium, such as a computer memory. Alternatively, a module, unit, or system may include a hard-wired device that performs operations based on hard-wired logic of the device. The modules or units shown in the attached figures may represent the hardware that operates based on software or hardwired instructions, the software that directs hardware to perform the operations, or a combination thereof. The hardware may include electronic circuits that include and/or are connected to one or more logic-based devices, such as microprocessors, processors, controllers, or the like. These devices may be off-the-shelf devices that are appropriately programmed or instructed to perform operations described herein from the instructions described above. Additionally or alternatively, one or more of these devices may be hard-wired with logic circuits to perform these operations.

As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

Generally, various embodiments of the subject matter described herein relate to parallel operation of high voltage (e.g., 1.7 kV, 3.3 kV, and/or the like) power modules and to the use of a high voltage adapter board for parallel operation of a plurality of modules that each include semiconductor switches. For example, each of the power modules may be of a dual type having two semiconductor switches (e.g., an upper switch and a lower switch) connected in series. The semiconductor switches may be configured to have a fast switching transients as wide band gap semiconductors, such as, SiC, GaN, and/or the like. The semiconductor switches may further include insulated gate bipolar transistors (IGBT), MOSFETS, diodes, and/or the like. The high voltage adapter board may be configured to be conductively coupled to a remotely connected driving circuit or a dual gate driver. For example, the driving circuit may be configured to serve a plurality of parallel connected high voltage power modules. The remotely driving circuit is physically separate from the high voltage adapter board, and is configured to instruct the semiconductor switches to activate and/or deactivate. Additionally or alternatively, the driving circuit may be mounted on top of one or more modules of the circuit board. Optionally, the modules may be configured to allow scalable converter designs in voltage and/or current. For example, the modules may be enclosed within a housing enabling the modules to be positioned in a close physical proximity to each other and connecting them accordingly to increase current and/or voltage. Additionally or alternatively, additional high voltage adapter boards may be electrically and/or conductively coupled to each other and to the modules to increase the voltage and/or current supported based on the arrangement.

The high voltage adapter board is an intermediate element used to drive multiple modules in parallel such that the trigger signals received at the high voltage adapter board are effectively synchronized downstream at each individual module, and as such current unbalances and/or delayed switching among the modules is prevented and/or mitigated. The high voltage adapter board may extend over the entire upper surface of the mid-plateau in each of the modules which are connected in parallel. The mid-plateau may correspond to a sunk cavity at a lower height than the maximum height of the module on the sides. Conductive traces, such as copper traces, may traverse along the high voltage adapter board. The conductive traces may form a tree structure of conductive traces of different widths and/or separations which extend from an input interface of the high voltage adapter board conductively coupled to the driver circuit to corresponding modules. Additionally or alternatively, the high voltage adapter board may include additional circuits configured to protect (e.g., clamping circuits) the input interfaces, terminals conductively coupled to the modules and/or the like.

At least one technical effect of various embodiments provides a scalable power of an inverter. At least one technical effect of various embodiments provides synchronously activating and/or deactivating a plurality of the semiconductor switches in parallel. At least one technical effect of various embodiments provides a remote driver circuit to the n-modules in parallel, and to decouple the high voltage aspects and part of the sensing aspects directly close to each module, instead of all together mixed at the driver circuit.

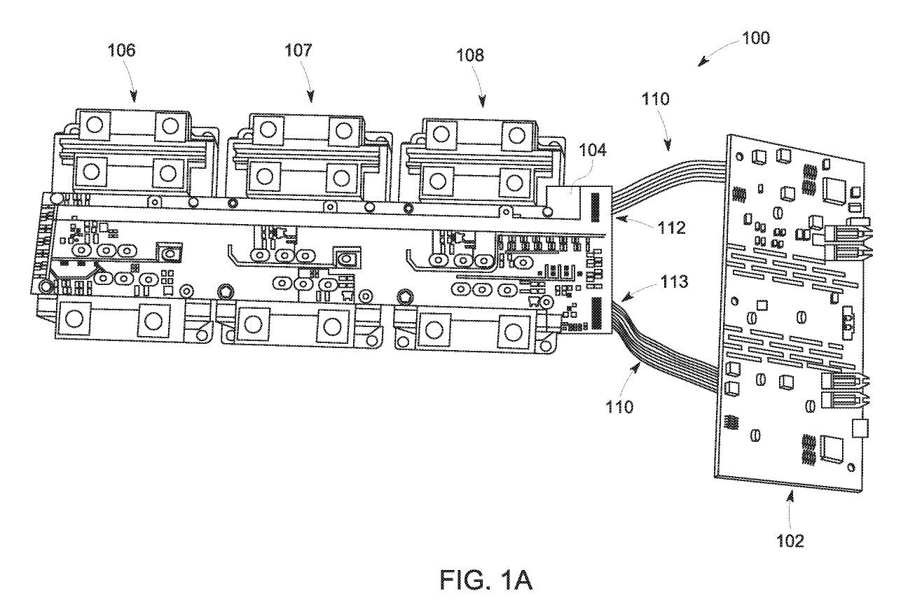

FIG. 1A illustrates a peripheral view of an embodiment of a power system 100. The power system 100 includes a plurality of modules 106-108 and a high voltage adapter board 104. The high voltage adapter board 104 may be fastened and/or conductively (e.g., electrically) coupled and/or connected to the modules 106-108. In connection with FIG. 1B, each of the modules 106-108 may include one or more semiconductor switches, such as an upper switch 160 and a lower switch 161 inside each module 106-108. The high voltage adapter board 104 may be a circuit board (e.g., printed circuit board) configured to synchronously active the one or more semiconductor switches. The upper switch 160 and the lower switch 161 may be wide-bandgap semiconductors. For example, fabrication of the upper switch 160 and/or the lower switch 161 may include silicon carbide, gallium arsenide, gallium phosphide, indium phosphide, cadmium telluride, aluminum gallium nitride, or gallium nitride.

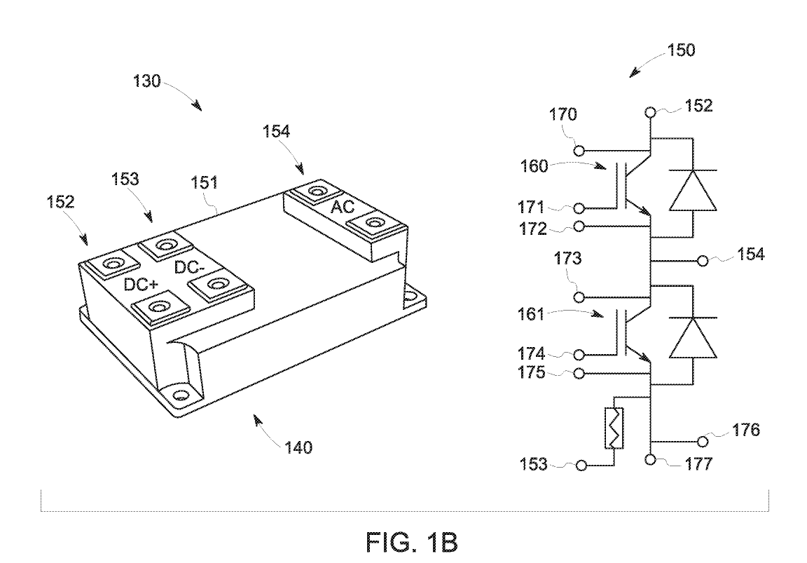

FIG. 1B illustrates an illustration 130 of an embodiment of the modules 106-108 of the power system 100. The schematic illustration 130 includes a peripheral view 140 and a schematic illustration 150 of the module 106. The upper switch 160 and the lower switch 161 are connected in series and are enclosed within a housing 151 of the modules 106-108. The modules 106-108 include a set of power terminals 152-154 and a set of auxiliary terminals 170-177. The auxiliary terminals 170-177 are conductively coupled to the high voltage adapter board 104 (e.g., terminals 216-221 shown in FIG. 2) and are controller by a driver circuit 102. The upper switch 160 and the lower switch 161 are driven independently from each other. For example, the upper switch 160 may be conductively coupled to conductive traces extending along (e.g., along an upper surface and/or within) the high voltage adapter board 104, and the lower switch may be conductively coupled to conductive traces extending along (e.g., along a lower surface and/or within) the high voltage adapter board 104. The modules 106-108 may be configured to be conductively coupled in parallel with respect to each other. For purposes of the present description, the term “parallel,” when used in regard to three-terminal devices, is used to refer to common connections with any two terminals of the three-terminal device. For example, each of the power terminals 152-154 of the modules 106-108 may be conductive coupled to each other to be configured in parallel, such as the power terminal 152 of the modules 106-108 are conductively coupled together, the power terminal 153 of the modules 106-108 are conductively coupled together, and the power terminal 154 of the modules 106-108 are conductively coupled together.

The one or more semiconductor switches (e.g., the upper switch 160, the lower switch 161) may be activated and/or deactivated based on an electrical signal (e.g., voltage, current) received from the high voltage adapter board 104 shown in FIG. 1A. For example, each of the semiconductor switches are conductively coupled to corresponding input interfaces 112-113 of the high voltage adapter board 104 via conductive traces. The input interfaces 112-113 may include a connector, a cable, a flexible circuit board, and/or the like. The conductive traces may be a conductive metal (e.g., copper, gold, aluminum, and/or the like) disposed on the upper surface, the lower surface, and/or within the high voltage adapter board 104 from the input interfaces 112-113 to corresponding semiconductor switches (e.g., the upper switch 160, the lower switch 161). For example, a first conductive trace may conductively couple the input interface 112 to the upper switch 160 of the module 106. In another example, a second conductive trace along the upper surface may conductively couple the input interface 112 to the upper switch 160 of the module 107.

The conductive traces along the upper surface, the lower surface, and/or within the high voltage adapter board 104 may be configured to have substantially the same and/or similar electrical properties (e.g., inductance, impedance) within a predetermined non-zero threshold (e.g., a percentage, a set value). Optionally, the predetermined non-zero threshold may define a set maximum difference between the electrical properties (e.g., inductance, of the conductive traces). For example, the predetermined non-zero threshold may be 20% such that the electrical properties such as the inductance and/or impedance of the conductive traces are not more than 20% different relative to each other. Additionally or alternatively, the predetermined non-zero threshold may represent set values of the electrical properties of the conductive traces. For example, the predetermined non-zero threshold may be 5 nano-Henries (nH) and 5 milli-Ohms (mOhms), such that the difference in inductance between the conductive traces does not exceed 5 nH and the difference in impedance between the conductive traces does not exceed 5 mOhms. It may be noted that the set values of the predetermined non-zero thresholds may be different.

The electrical properties of the conductive traces affect when the electrical signal at the input interfaces 112-113 reach the corresponding upper and/or lower switches of the modules 106-108. For example, conductive traces having the same and/or similar electrical properties conduct the electrical signal from the input interfaces 112-113 to the corresponding modules 106-108 concurrently and/or simultaneously. The electrical properties of the conductive traces may be adjusted based on a cross-sectional area (e.g., width, height) of the conductive traces. Additionally or alternatively, the electrical properties of the conductive traces may be adjusted based on a length of the conductive traces.

The electrical signal may be communicated and/or transmitted by the driver circuit 102 conductively coupled to the input interfaces 112-113. The driver circuit 102 is configured to activate (e.g., ON) and/or deactivate (e.g., OFF) the switches of the modules 106-108 based on the generated electrical signals by the driver circuit 102. For example, the driver circuit 102 may be configured to turn on a select set of the switches (e.g., the upper switch 160, the lower switch 161) by providing a positive voltage across the gate and emitter terminals of the select set of switches. The driver circuit 102 as shown in FIG. 1A may be disposed and/or positioned remotely with respect to the high voltage adapter board 104. For example, the driver circuit 102 may be located outside and/or away from the high voltage adapter board 104 having conductive leads 110 configured to conductively couple the output of the driver circuit 102 to the input interfaces 112-113. Optionally, the high voltage adapter board 104 may include a clamping circuit. It may be noted that the conductive leads 110 may introduce a high inductance, which can, under certain circumstances, contribute to a voltage build-up across the gate and emitter terminals of the switches of the modules 106-108. The clamping circuit is configured to mitigate the effect of the high inductance introduced by the conductive leads 110 by preventing the voltage to rise beyond a non-zero predetermined clamping threshold relative to the electrical signal generated by the driver board 102. For example, the non-zero predetermined clamping threshold may be a set percentage (e.g., 10%, 20%, and/or the like) and/or magnitude (e.g., 2V, 3V, and/or the like) above and/or below the voltage and/or current of the electrical signal generated by the driver board 102. Optionally, the clamping circuit may be a part of the modules 106-108. Additionally or alternatively, the driver circuit 102 may be mounted directly and/or indirectly to the high voltage adapter board 104 and/or one or more of the modules 106-108, thereby eliminating the conductive leads 110. Additionally or alternatively, the driver circuit 102 may be a part of and/or integrated with the high voltage adapter board 104, such as a single printed circuit board that includes the driver circuit 102 and the high voltage adapter board 104.

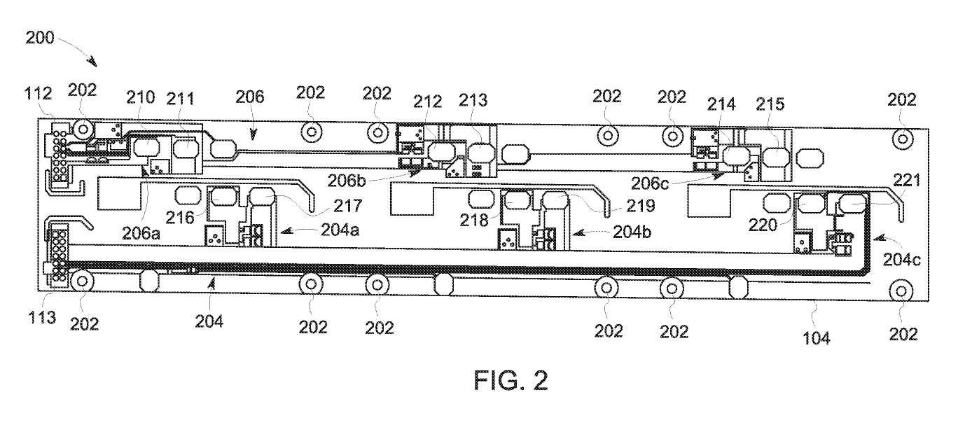

FIGS. 2 and 3 illustrate schematic illustrations 200 and 300 of an embodiment of the high voltage adapter board 104. The high voltage adapter board 104 is shown having a series of openings 202. The openings 202 may be configured to mechanically couple the high voltage adapter board 104 to the modules 106-108, using for example, a plurality of screws, fasteners, known mechanical fixation means, and/or the like. For example, fasteners are inserted through each respective opening 202 to facilitate coupling the high voltage adapter board 104 to the modules 106-108.

The high voltage adapter board 104 shown in FIGS. 2 and 3 include a first and second series of conductive traces 204, 206. The first series of conductive traces 204 are configured to extend along the lower surface of the high voltage adapter board 104. The first series of conductive traces 204 are configured to conductively couple the input interface 113 to terminals 216-221 of the lower switches of the modules 106-108. For example, the pair of conductive traces 204a conductively couples the input interface 113 to the terminals 216 and 217. The terminal 216 may represent an emitter terminal and the terminal 217 may represent a gate terminal of the lower switch of the module 106. In another example, the pair of conductive traces 204b conductively couples the input interface 113 to the terminals 218 and 219. The terminal 218 may represent an emitter terminal and the terminal 219 may represent a gate terminal of the lower switch of the module 107. In another example, the pair of conductive trace 204c conductively couples the input interface 113 to the terminals 220 and 221. The terminal 220 may represent an emitter terminal and the terminal 221 may represent a gate terminal of the lower switch of the module 108.

The second series of conductive traces 206 are configured to conductively couple the input interface 112 to terminals 210-215 of the upper switches of the modules 106-108. For example, the pair of conductive traces 206a conductively couples the input interface 112 to the terminals 210 and 211. The terminal 210 may represent a gate terminal and the terminal 211 may represent an emitter terminal of the upper switch of the module 106. In another example, the pair of conductive traces 206b conductively couples the input interface 112 to the terminals 212 and 213. The terminal 212 may represent a gate terminal and the terminal 213 may represent an emitter terminal of the upper switch of the module 107. In another example, the pair of conductive traces 206c conductively couples the input interface 112 to the terminals 214 and 215. The terminal 214 may represent a gate terminal and the terminal 215 may represent an emitter terminal of the upper switch of the module 108.

Each of the pairs of conductive traces 204a-c and/or 206a-c may be configured to have similar and/or the same electrical properties within the predetermined non-zero threshold. For example, geometric shapes of the pairs of conductive traces 204a-c are configured such that the respective electrical properties (e.g., inductance, impedance) of the pairs of conductive traces 204a-c are similar to and/or substantially the same with respect to each other within the predetermined non-zero threshold. Thereby, the electrical signals at the input interface 113 are received concurrently and/or simultaneously via the pairs of conductive traces 204a-c at the terminals 216-221.

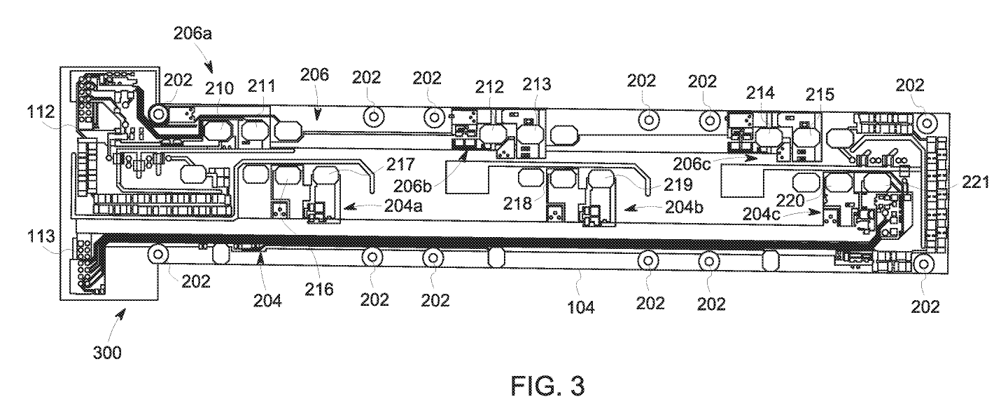

FIG. 4A illustrates a peripheral view 400 of an embodiment of the series of conductive traces 206. Each of the pairs of conductive traces 206a-c may include a terminal 410-412. The terminals 410-412 may be configured to be conductively coupled to corresponding terminals (e.g., 210-221) of the modules 106-108. The pairs of conductive traces 206a-c may have different geometric shapes (e.g., lengths, cross-sectional area, and/or the like) such as different lengths 414-416 and/or cross-sectional areas extending from the input interface 112 to corresponding terminals 210-215. For example, the pair conductive traces 206a has the length 414 from the input interface 112 to the terminals 210 and 211, the pair of conductive traces 206b has the length 415 from the input interface 112 to the terminals 212 and 213, and the pair of conductive traces 206c has the length 416 from the input interface 112 to the terminals 214 and 215. Based on the different lengths 414-416, a cross-sectional area of the pairs of conductive traces 206a-c, shown in FIG. 4B, are configured such that the electrical properties of the pairs of conductive traces 206a-c are similar and/or the same with respect to each other within the predetermined non-zero threshold.

FIG. 4B illustrates a cross-sectional area view 450 of an embodiment of the series of conductive traces 206. The pairs of conductive traces 206a-c are configured to have different geometric shapes, such as different widths 402-404 to adjust the electrical properties of the conductive traces 206a-c. Each pair of conductive traces 206a-c are separated from each other by a distance 452 and have a height 454. The distance 452 may represent a dielectric separating different layers (e.g., printed circuit board layers) of the high voltage adapter board 104. Additionally or alternatively, the distance 452 may represent a distance separating each conductive trace forming the pair of conductive trace 206a-c. The widths 402-404 of the pairs of conductive traces 206a-c are configured to adjust the electrical properties (e.g., inductance, impedance) of the pairs of conductive traces 206a-c from the input interface 112 to corresponding terminals 210-215 at each of the modules 106-108, to be similar and/or substantially the same if balancing is required, or to be a determined value in general with respect to each other within the predetermined non-zero threshold.

Optionally, the cross-sectional areas of the conductive traces 206a-c may be based on the lengths 414-416. For example only, the differences in cross-sectional areas of the pairs of conductive traces 206a-c are configured to account for the difference in lengths 414-416 have on the electrical properties of the pairs of conductive traces 206a-c. The pair of conductive traces 206a has the shortest length 414 relative to the lengths 415-416 and the smallest cross-sectional area relative to the pairs of conductive traces 206b and 206c. For example, the pair of conductive traces 206a may have the width 402 of 1.25 mm and height 454 of 0.035 mm. The pair of conductive traces 206b having the length 415 is between the lengths 414 and 416 of the pairs of conductive traces 206a, 206c and has a cross-sectional area between the pair of conductive traces 206a and 206c. For example, the pair of conductive traces 206b may have the width 403 of 5 mm and height 454 of 0.035 mm. The pair of conductive traces 206c has the largest length 416 relative to the lengths 414-415 and has the largest cross-sectional area relative to the pairs of conductive traces 206a-b. For example, the pair of conductive traces 206c may have a width 404 of 6 mm and height 454 of 0.035 mm.

Based on the differences in the geometric shapes, such as the cross-sectional areas, of the pairs of conductive traces 206a-c, the electrical properties of the pairs of conductive traces 206a-c are similar to and/or substantially the same with respect to each other. For example, the predetermined non-zero threshold may be a set value of 1 nH for the inductance and 5.5 mOhms for the impedance. The pairs of conductive traces 206a-c may have inductances of 11.617 nH, 11.647 nH, and 11.783 nH, respectively. In another example, the pairs of conductive traces 206a-c may have resistances of 25.183 mOhms, 23.828 mOhms, and 19.954 mOhms, respectively. The difference in the inductances and the impedances between the pairs of conductive traces 206a-c are below the predetermined non-zero threshold thereby the electrical properties of the pairs of conductive traces 206a-c are similar and/or substantially the same.

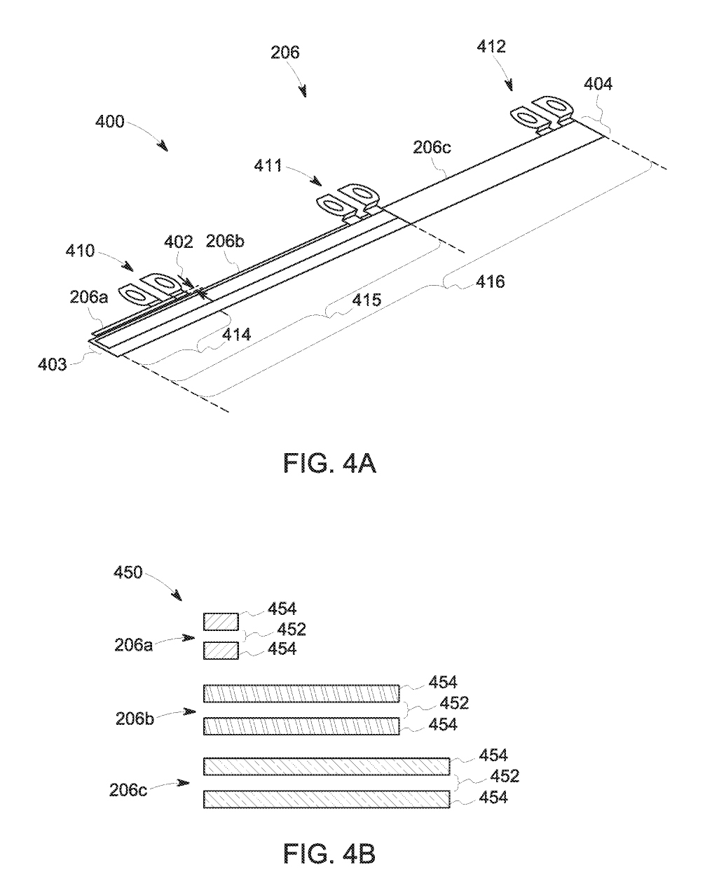

Additionally or alternatively, the distances 452, the height 454, the lengths 414-416, the widths 402-404, and/or the like may be adjusted to alter the electrical properties of the pairs of conductive traces 206a-c. Optionally, in connection with FIGS. 5A-B, the geometric shape of a series of conductive traces 506 may be the same and/or similar.

FIG. 5A illustrates a peripheral view 500 of an embodiment of the series of conductive traces 506. Each pair of the conductive traces 506a-c may include terminals 510-512. The terminals 510-512 may be similar to and/or the same as the terminals 410-412. The pairs of conductive traces 506a-c have the same length 508 extending from the input interface 112. For example, the pairs of conductive traces 506a-b are configured to extend along a plurality of non-orthogonal directions to have the length 508 similar to and/or the same as the length 508 of the pair of conductive traces 506c. Based on the common length 508 of the pairs of conductive traces 506a-c, a cross-sectional area of the pairs of conductive traces 506a-c, shown in FIG. 5B, are configured such that the electrical properties of the pairs of conductive traces 506a-c are similar and/or the same with respect to each other within the predetermined non-zero threshold.

FIG. 5B illustrates a cross-sectional area view 550 of an embodiment of the series of conductive traces 506. Pairs of conductive traces 506a-c are configured to have the same and/or similar cross-sectional area. For example, based on the common length 508 of the pairs of conductive traces 506a-c the cross-sectional area of the pairs of conductive traces 506a-c may be configured to be the same and/or similar to have the electrical properties of the pairs of conductive traces 506a-c to be similar and/or the same with respect to each other within the predetermined non-zero threshold. The pairs of conductive traces 506a-c have a common width 504 and height 554 to form the cross-sectional area of the pairs of conductive traces 506a-c be the same and/or similar. Each pair of conductive traces 506a-c are separated from each other by a distance 552. The distance 554 may be similar to and/or the same as the distance 454 of FIG. 4B.

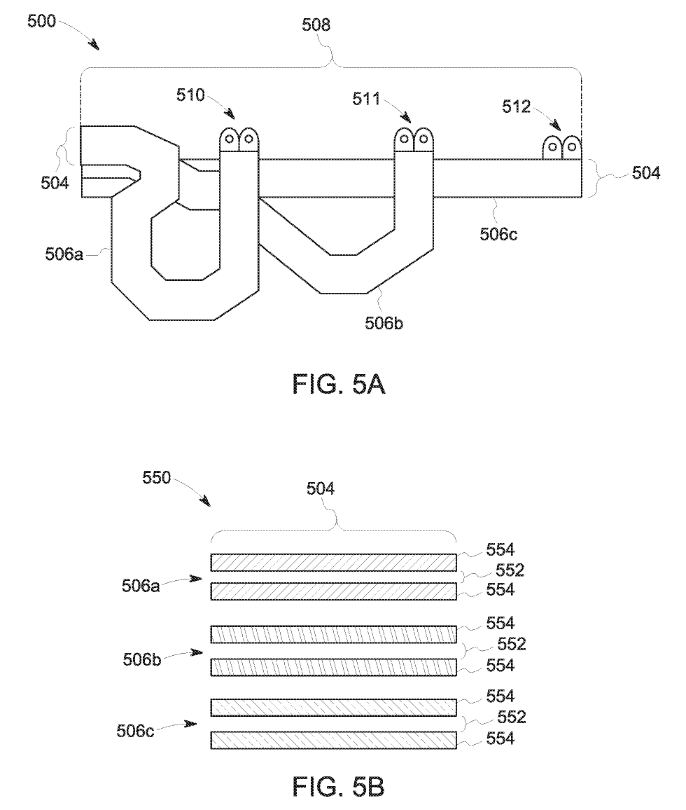

Additionally or alternatively, in connection with FIGS. 6A-B, a spatial relationship between each pair of conductive traces 602-604 may be configured such that the electrical characteristics (e.g., inductance, impedance) of the pairs of conductive traces 602-604 are similar and/or substantially the same within the non-zero predetermined threshold.

FIGS. 6A-B illustrate cross-sectional area views 600, 650 of embodiments of a series of conductive traces 602-604. The cross-sectional area views 600, 650 each show different spatial relationships between the pairs of conductive traces 602-604.

For example, the cross-sectional area view 600 illustrates three pairs of conductive traces 602-604 formed by the conductive traces 602a-604b. The conductive traces 602a-604b each may have a width of 614 and a height of 616. The lengths of the pairs of conductive traces 602-604 may be similar to and/or the same as the pairs of conductive traces 206a-206c. For example, the pair of conductive traces 602 may have the length 414, the pair of conductive traces 604 may have the length 415, and the pair of conductive traces 606 may have the length 416. The spatial relationship, such as distances 606-608, between the conductive traces 602a-604b forming the pairs of conductive traces 602-604 are configured such that the electrical characteristics (e.g., inductance, impedance) of each pair of conductive traces 602-604 are similar and/or substantially the same within the non-zero predetermined threshold. For example, the spatial relationship may represent distances 606-608 between each of the conductive traces 602a-604b forming the pairs of conductive traces 602-604. The distances 606-608 may represent a composite material, such as a dielectric, separating the conductive traces 602a-604b that form the pairs of conductive traces 602-604. For example, the conductive traces 602a-b forming the pair of conductive traces 602 is separated by the distance of 606, the conductive traces 603a-b forming the pair of conductive traces 603 is separated by the distance 607, and the conductive traces 604a-b forming the pair of conductive traces 604 is separated by the distance 608. Each of the distances 606-608 are different with respect to each other. For example, the distance 606 is larger relative to the distances 607 and 608, and the distance 607 is larger relative to the distance 608. The distances 606-608 are configured to adjust the electrical characteristics of the pairs of conductive traces 606-608 between the conductive traces 602. For example, the distance 606 between the conductive traces 602a-b is configured to adjust the electrical characteristics of the pair of conductive traces 602 to be similar and/or substantially the same within the non-zero predetermined threshold as the pairs of conductive traces 603-604. In another example, the distance 607 between the conductive traces 603a-b is configured to adjust the electrical characteristics of the pair of conductive traces 603 to be similar and/or substantially the same within the non-zero predetermined threshold as the pairs of conductive traces 602, 604.

In another example, the cross-sectional area view 650 illustrates the three pairs of conductive traces 602-604 having the same distance 606 between the conductive traces 602a-604b. The cross-sectional area view 650 illustrates lateral offsets 610, 612 of the pairs of conductive traces 602-603. The spatial relationship, such as the lateral offsets 610, 612, between the conductive traces 602a-603b forming the pairs of conductive traces 602-603 are configured such that the electrical characteristics (e.g., inductance, impedance) of each pair of conductive traces 602-604 are similar and/or substantially the same within the non-zero predetermined threshold. For example, the spatial relationship may represent lateral offsets 610, 612 between each of the conductive traces 602a-603b forming the pairs of conductive traces 602-603. The lateral offsets 610, 612 corresponds to a misalignment between the conductive traces 602a-b forming the pair of conductive traces 602, and the conductive traces 603a-b forming the pair of conductive traces 603. For example, the lateral offset 610 is formed by a shift along an arrow 618 of a position and/or location of the conductive trace 602b with respect to the conductive trace 602a, such that edges 620 and 621 are not aligned. Each of the lateral offsets 610, 612 are different with respect to each other. For example, the lateral offset 610 is larger relative to the lateral offset 612. The lateral offsets 610, 612 are configured to adjust the electrical characteristics of the pairs of conductive traces 602-603 to be similar to and/or substantially the same as the electrical characteristics of the pair of conductive traces 604, which has no lateral offset. In an embodiment, a size of the lateral offsets 610, 612 may be based on the different in lengths 414-416 between the pairs of conductive traces 602-604. For example, the pair of conductive traces 602 have the length 414, which is smaller relative to the pairs of conductive traces 603-604 having lengths 415 and 416, respectively. Based on the length 414, the lateral offset 610 between the conductive traces 602a-b may be larger relative to the lateral offset 612.

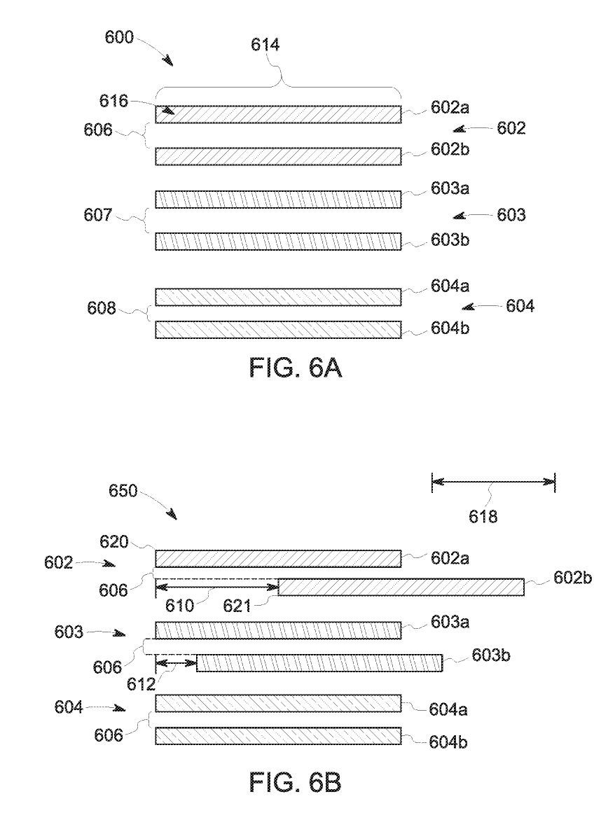

Additionally or alternatively, in connection with FIG. 7, the high voltage adapter board may utilize first and second conductive traces 702, 703 conductively coupled to terminals 706-708, 710-712 of the modules 106-108.

FIG. 7 illustrates a peripheral view 700 of an embodiment of the first and second conductive traces 702, 703. The first conductive trace 702 is conductively coupled to an input interface 701 and the one or more terminals 706-708. The input interface 701 may be similar to and/or the same as one of the input interfaces 112, 113. The second conductive trace 703 is conductively coupled to the input interface 701 and the one or more terminals 710-712. For example, current flows from the input interface 701 to the terminals 706-708 via the first conductive trace 702, and returns to the input interface 701 from the terminals 710-712 via the second conductive trace 703. The peripheral view 700 of the first and second conductive paths 702, 703 are shown subdivided into lengths 720-724. The lengths 720-722 are similar and/or substantially the same with each other, and the lengths 723-724 are similar and/or substantially the same with each other. The one or more terminals 706-708 may be conductive coupled to gate terminals and one or more terminals 710-712 may be conductive coupled to emitter terminals of the upper or lower switches 160, 161 of the modules 106-108, respectively. For example, the terminals 706 and 710 may be conductive coupled to the module 106, the terminals 707 and 711 may be conductive coupled to the module 107, and the terminals 708 and 712 may be conductively coupled to the module 108. It may be noted that the first and second conductive traces 702, 703 do not overlap. Additionally or alternatively, the first conductive trace 702 and the second conductive trace 703 are not each a pair of conductive traces.

Positions of the terminals 706-708, 710-712 with respect to the first and second conductive paths 702, 703 are configured such that the current paths between the input interface 701 and the modules 106-108 are similar and/or substantially the same for synchronous activation of the switches (e.g., upper or lower switches 160, 161 of the modules 106-108). For example, the current path between the module 106 and the input interface 701 are based on the terminals 706 and 710. The current path along the first conductive trace 702 to the terminal 706 includes the lengths 720-722, the length 723, and the additional lengths 721-722 or a total of 6 segments. The current path along the second conductive trace 703 from the terminal 710 includes the lengths 724 and the length 720 or a total of 2 segments. In another example, the current path between the module 108 and the input interface 701 are based on the terminals 708 and 712. The current path along the first conductive trace 702 to the terminal 708 includes the lengths 720-722 and the length 723 or a total of 4 segments. The current path along the second conductive trace 703 from the terminal 712 includes the lengths 720-722 and the length 724 or a total of 4 segments. Thereby, the current paths for both of the modules 106 and 108 are 8 segments shown in the peripheral view 700 are similar and/or the same.

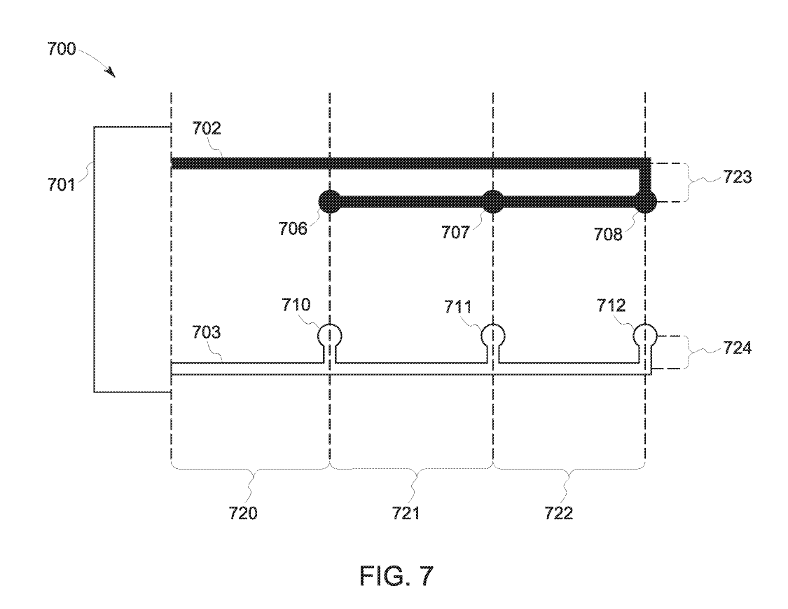

In connection with FIG. 8, the high voltage adapter board 104 may include additional circuitry, such as an isolation circuit 804, clamping circuit 802, and/or the like configured to insulate the switches of the modules 106-108.

FIG. 8 illustrates a circuit diagram 800 of an embodiment of a portion of the high voltage adapter board 104. The circuit diagram 800 includes the input interface 807 conductively coupled to the select semiconductor switch (e.g., upper switch 160 or lower switch 161) via one or more terminals of the one or more modules 106-108. For example, the input interface 807 may be conductively coupled to a gate terminal 812, a collector terminal 810, and an emitter terminal 814. The input interface 807 may be similar to and/or the same as the input interfaces 112, 113. For example, the input interface 807 may be conductively coupled to the driver circuit 102. Optionally, input interface 807 and the emitter terminal 814 may be conductively coupled to emitter resistors 808 configured to reduce a current at the emitter terminal 814. The gate terminal 812 may be conductively coupled to a gate terminal (e.g., 210, 212, 214, 217, 219, 221) of the select semiconductor switch, and the emitter terminal 814 may be conductively coupled to an emitter terminal (e.g., 211, 213, 215, 216, 218, 220) of the select semiconductor switch.

The circuit diagram includes a clamping circuit 802 conductively coupled to the gate terminal 812 and the emitter terminal 814. The clamping circuit 802 may include a diode and/or one or more Zener diodes. The clamping circuit 802 may be configured to prevent the voltage across the gate and emitter terminals 812, 814 (e.g., gate-emitter voltage) of the select semiconductor switch from exceeding a voltage limit, above which the select semiconductor switch could be damaged and/or operate erroneously. The voltage limit may be specified by the manufacturer of the select semiconductor switch. For example, depending on the type and design signals of the select semiconductor switch, the voltage limit may be approximately 20 volts. During normal operation, the clamping circuit 802 is configured to not significantly affect the gate-emitter voltage and allows the gate-emitter voltage to reach or exceed the specified turn-on voltage of the select semiconductor switch. The clamping circuit 802 may be configured to reduce the gate-emitter voltage across the select semiconductor switch when the gate-emitter voltage exceeds a voltage such as a clamping threshold voltage. Above the clamping threshold voltage, the clamping circuit may be activated, thus preventing an excessive voltage build-up across the select semiconductor switch. The clamping threshold voltage may be between the turn-on voltage of the select semiconductor switch and the voltage limit specified for the select semiconductor switch. Optionally, the clamping threshold voltage may correspond to a breakdown voltage of the clamping circuit 802 based on the diode and/or Zener diodes of the clamping circuit 802.

The collector terminal 810 may be conductively coupled to a collector terminal of the select semiconductor switch. The circuit diagram 800 includes a dynamic voltage divider circuit 806 configured to reduce the voltage at the collector terminal 810. The dynamic voltage divider circuit 806 may include a series of capacitors. For example, the capacitors are conductively coupled in parallel to a resistor, which is configured such that a frequency response of a frequency range of interest is flat (e.g., mitigate, reduce, and/or result in no attenuation or peaks).

The circuit diagram 800 includes an isolation circuit 804 conductively coupled to the collector terminal 710 and the input interface 807. The isolation circuit 804 is configured to isolate the driver circuit 102 and/or the input interface 807 from the voltage at the collector terminal 710. The isolation circuit may include one or more diodes, a switch (e.g., MOSFET, BJT, semiconductor switch, and/or the like). Additionally or alternatively, the isolation circuit 804 and/or optional circuits of the circuit diagram 800 (e.g., measurement circuit, compensation circuit) may be similar to and/or the same as an operational circuitry as described in U.S. patent application entitled, “SYSTEMS AND METHODS FOR VOLTAGE SENSING,” having attorney docket No. 314006-1, which is incorporated herein by reference in its entirety.

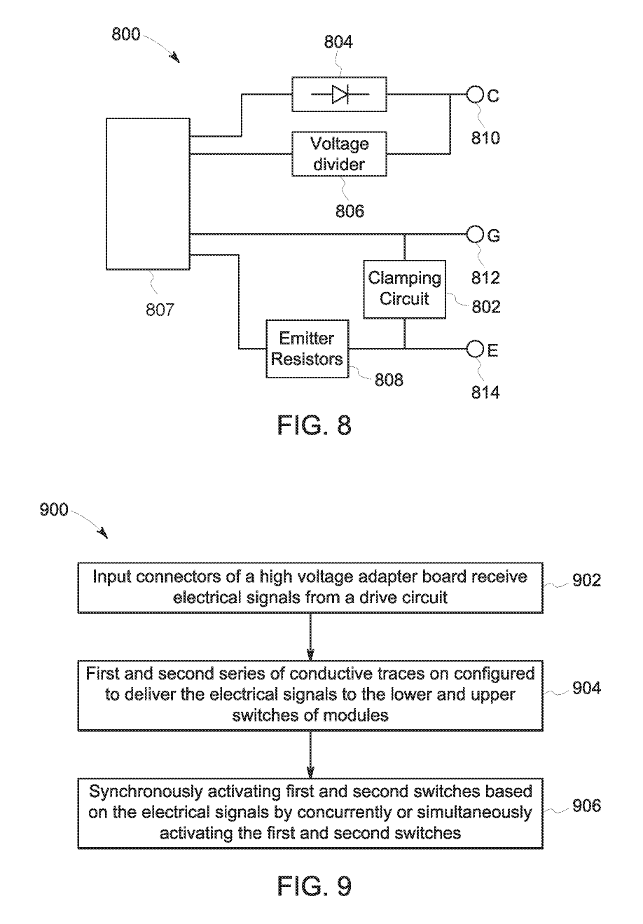

FIG. 9 is a flow chart of an embodiment of a method 900 for controlling semiconductor switches. The method 900, for example, may employ or be performed by structures or aspects of various embodiments discussed herein. In various embodiments, certain operations may be omitted or added, certain operations may be combined, certain operations may be performed simultaneously, certain operations may be performed concurrently, certain operations may be split into multiple operations, certain operations may be performed in a different order, or certain operations or series of operations may be re-performed in an iterative fashion. In various embodiments, portions, aspects, and/or variations of the method 900 may be able to be used as one or more algorithms to direct hardware to perform one or more operations described herein.

Beginning at 902, the input interfaces 112, 113 of the high voltage adapter board 104 receiving an electrical signal from the driver circuit 102. For example, the driver circuit 102 may deliver a voltage and/or current along the conductive leads 110 to the input interfaces 112, 113.

At 904, the first and second series of conductive traces 204 and 206 are configured to deliver the electrical signals to the lower and upper switches 161, 160, respectively, of the modules 106-108. For example, the conductive trace 206a of the second series of conductive trace 206 may extend along an upper surface, lower surface, and/or within the high voltage adapter board 104 and is conductively coupled to the input interface 114 and the upper switch 160, at the terminals 210 and 211 of the module 106. In another example, the conductive trace 206b of the second series of conductive trace 206 may extend along an upper surface, lower surface, and/or within the high voltage adapter board 104 and is conductively coupled to the input interface 114 and the upper switch 160, at the terminals 212 and 213 of the module 107.

At 906, synchronously activating the first and second switches based on the electrical signal by concurrently and/or simultaneously activating the first and second switches. For example, the conductive traces 206a-b may be configured to have similar and/or the same electrical properties within a predetermined non-zero threshold. For example, the cross-sectional areas of the conductive traces 206a-b are configured such that the electrical properties of the conductive traces 206a-b are similar to and/or substantially the same with respect to each other within the predetermined non-zero threshold. Thereby, the electrical signals at the input interface 114 are received concurrently and/or simultaneously via the conductive traces 206a-b at the terminals 210-213 to synchronously activate the upper switches of the modules 106-107.

It should be noted that the particular arrangement of components (e.g., the number, types, placement, or the like) of the illustrated embodiments may be modified in various alternate embodiments. For example, in various embodiments, different numbers of a given module or unit may be employed, a different type or types of a given module or unit may be employed, a number of modules or units (or aspects thereof) may be combined, a given module or unit may be divided into plural modules (or sub-modules) or units (or sub-units), one or more aspects of one or more modules may be shared between modules, a given module or unit may be added, or a given module or unit may be omitted.

As used herein, a structure, limitation, or element that is “configured to” perform a task or operation is particularly structurally formed, constructed, or adapted in a manner corresponding to the task or operation. For purposes of clarity and the avoidance of doubt, an object that is merely capable of being modified to perform the task or operation is not “configured to” perform the task or operation as used herein. Instead, the use of “configured to” as used herein denotes structural adaptations or signals, and denotes structural requirements of any structure, limitation, or element that is described as being “configured to” perform the task or operation. For example, a processing unit, processor, or computer that is “configured to” perform a task or operation may be understood as being particularly structured to perform the task or operation (e.g., having one or more programs or instructions stored thereon or used in conjunction therewith tailored or intended to perform the task or operation, and/or having an arrangement of processing circuitry tailored or intended to perform the task or operation). For the purposes of clarity and the avoidance of doubt, a general purpose computer (which may become “configured to” perform the task or operation if appropriately programmed) is not “configured to” perform a task or operation unless or until specifically programmed or structurally modified to perform the task or operation.

It should be noted that the various embodiments may be implemented in hardware, software or a combination thereof. The various embodiments and/or components, for example, the modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a solid state drive, optic drive, and the like. The storage device may also be other similar means for loading computer programs or other instructions into the computer or processor.

As used herein, the term “computer,” “controller,” and “module” may each include any processor-based or microprocessor-based system including systems using microcontrollers, reduced instruction set computers (RISC), application specific integrated circuits (ASICs), logic circuits, GPUs, FPGAs, and any other circuit or processor capable of executing the functions described herein. The above examples are exemplary only, and are thus not intended to limit in any way the definition and/or meaning of the term “module” or “computer.”

The computer, module, or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer, module, or processor as a processing machine to perform specific operations such as the methods and processes of the various embodiments described and/or illustrated herein. The set of instructions may be in the form of a software program. The software may be in various forms such as system software or application software and which may be embodied as a tangible and non-transitory computer readable medium. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program. The individual components of the various embodiments may be virtualized and hosted by a cloud type computational environment, for example to allow for dynamic allocation of computational power, without requiring the user concerning the location, configuration, and/or specific hardware of the computer system.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f) unless and until such claim limitations expressly use the phrase “means for” followed by a statement of function void of further structure.

This written description uses examples to disclose the various embodiments, and also to enable a person having ordinary skill in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or the examples include equivalent structural elements with insubstantial differences from the literal language of the claims.

What is claimed is:

1. A system comprising:
a high voltage adapter board coupled to a first module and a second module, wherein the first module is conductively coupled to a first terminal of the high voltage adapter board, a first conductive trace extending along the high voltage adapter board and is conductively coupled to the first terminal, the second module conductively coupled to a second terminal of the high voltage adapter board and a second conductive trace extending along the high voltage adapter board and is conductively coupled to the second terminal, wherein the first conductive trace and the second conductive trace are each conductively coupled to an input interface; and
a first switch of the first module and a second switch of the second module, wherein the first switch is conductively coupled to the first terminal and the second switch is conductively coupled to the second terminal, wherein the first and second conductive traces are configured to have an inductance substantially the same such that the first and second conductive traces are configured to synchronously activate the first and second switches.

2. The module system of claim 1, further comprising a driver circuit conductively coupled to the input interface, the driver circuit being configured to communicate an electrical signal to the high voltage adapter board.

3. The module system of claim 2, wherein the driver circuit is positioned remotely with respect to the high voltage adapter board.

4. The module system of claim 2, wherein the driver circuit is mounted to the high voltage adapter board.

5. The module system of claim 1, wherein the high voltage adapter board includes a driver circuit, wherein the driver circuit is configured to communicate an electrical signal to the input interface.

6. The module system of claim 1, wherein a geometric shape of at least one of the first conductive trace or the second conductive trace are configured such that the respective inductances of the first conductive trace and the second conductive trace are substantially the same.

7. The module system of claim 6, wherein the geometric shape corresponds to a cross-sectional area or a length.

8. The module system of claim 1, wherein the first and second switches are wide-bandgap semiconductors, the first and second switches include silicon carbide, gallium arsenide, gallium phosphide, indium phosphide, cadmium telluride, aluminum gallium nitride, or gallium nitride.

9. The module system of claim 1, wherein, a clamping circuit is conductively coupled to each of the terminal pairs of the high voltage board.

10. The module system of claim 1, further comprising a fourth and fifth conductive traces, wherein the first and fourth conductive traces represent a first pair of conductive traces extending along first adjacent layers of the high voltage adapter board, and the second and fifth conductive traces correspond to a second pair of conductive traces extending along second adjacent layers.

11. The module system of claim 10, wherein a spatial relationship between the first and fourth conductive traces are configured such that the inductances of the first pair of conductive traces and the second conductive traces are substantially the same.

12. The module system of claim 11, wherein the spatial relationship corresponds to at least one of a distance between the first and fourth of conductive traces with respect to each other, or a lateral offset between the first and fourth conductive traces with respect to each other.

13. The module system of claim 1, wherein the input interface includes at least one of a connector, a cable, or a flexible circuit board.

14. The module system of claim 1, wherein the first and second modules each include an upper switch and a lower switch such that the first switch and second switch correspond to one of the upper switch or the lower switch.

15. A method comprising:
receiving an electrical signal at an input interface of a high voltage adapter board;
delivering the electrical signals to first and second switches along corresponding first and second conductive traces, wherein the first conductive trace extends along the high voltage adapter board and is conductively coupled to the input interface and the first switch, the second conductive trace extending along the high voltage adapter board and is conductively coupled to the input interface and the second switch, wherein the first and second conductive traces are each configured to have an inductance substantially the same; and
synchronously activating the first and second switches based on the electrical signal.

16. The method of claim 15, further comprising delivering the electrical signal to the input interface from a driver circuit conductively coupled to the input interface, wherein the driver circuit board is positioned remotely with respect to the high voltage adapter board or is mounted to the high voltage adapter board.

17. The method of claim 15, further comprising adjusting a geometric shape of at least one of the first conductive trace or the second conductive trace to configure the respective inductances of the first and second conductive traces to be substantially the same, wherein the adjusting of the geometric shape includes at least one of adjusting a cross-sectional area or a length.

18. The method of claim 15, wherein the first conductive trace corresponds to a first pair of conductive traces extending along first adjacent layers of the high voltage adapter board, and the second conductive trace corresponds to a second pair of conductive traces extending along second adjacent layers; and
further comprising adjusting a spatial relationship between at least one of the first pair of conductive traces or the second pair of conductive traces to adjust the inductance to be substantially the same.

19. The method of claim 15, wherein the first and second switches are fitted with wide-bandgap semiconductors, wherein the first and second switches include silicon carbide or gallium nitride.

20. A system comprising:
a high voltage adapter board connected to a plurality of modules, wherein each module includes a first switch conductively coupled to an input interface through conductive traces along the high voltage board, each of the conductive traces are configured to have an inductance substantially the same such that the conductive traces are configured to synchronously activate the corresponding first switches based on an electrical signal; and
a driver circuit positioned remotely with respect to the high voltage adapter board, wherein the driver circuit is conductively coupled to the input interface and communicate the electrical signal to the high voltage adapter board.
